(19) United States
(12) Patent Application Publication
(10) Pub. No.: US 2015/0256204 A1
(43) Pub. Date: Sep. 10, 2015

(54) MEMORY CONTROLLER, STORAGE DEVICE AND MEMORY CONTROL METHOD

(71) Applicant: Kabushiki Kaisha Toshiba, Minato-ku (JP)

(72) Inventors: Osamu TORII, Setagaya (JP); Toshitake YAEGASHI, Yokkaichi (JP)

(73) Assignee: Kabushiki Kaisha Toshiba, Minato-ku (JP)

(21) Appl. No.: 14/452,679

(22) Filed: Aug. 6, 2014

Related U.S. Application Data
(60) Provisional application No. 61/949,714, filed on Mar. 7, 2014.

(51) Int. Cl. H03M 13/29; G06F 11/10

(52) U.S. Cl. CPC H03M 13/29; G06F 11/1068

(57) ABSTRACT

According to one embodiment, a memory controller includes a first encoder configured to generate a first codeword by encoding first data and generate a second codeword by encoding second data; an operation unit configured to perform an exor operation with at least the first codeword and the second codeword as inputs to generate a first exor-codeword; and a second encoder configured to encode the first exor-codeword to generate a second-stage parity; wherein the first codeword, the second codeword, and the second-stage parity are written to a nonvolatile memory.

### CROSS-REFERENCE TO RELATED APPLICATIONS

This application is based upon and claims the benefit of priority from U.S. Provisional Application No. 61/949,714, filed on Mar. 7, 2014; the entire contents of which are incorporated herein by reference.

### FIELD

E Embodiments described herein relate generally to a memory controller, a storage device, and a memory control method.

### BACKGROUND

When user data stored in a memory is read out from the memory, there is a case where the user data is changed into a different value from an original value or if data transmitted from a transmitting device is received in a receiving device, there is a case where the received data is changed into a value different from the original value. In order to address to the above problems, a method that the user data is error-correction encoded to generate parity data and the user data and the parity are managed as a pair is generally suggested.

### BRIEF DESCRIPTION OF THE DRAWINGS

FIG. 1 is a block diagram illustrating a configuration example of a storage device according to a first embodiment;

FIG. 2 is a view illustrating one example of an encoding configuration of the first embodiment;

FIG. 3 is a view illustrating one example of the encoding configuration when a group includes three or more user data;

FIG. 4 is a view illustrating an example of an encoding procedure of the first embodiment;

FIG. 5 is a view illustrating an example of a decoding procedure of the first embodiment;

FIG. 6 is a view illustrating a configuration example of an encoder;

FIG. 7 is a view illustrating a configuration example of a decoder;

FIG. 8 is a view illustrating an example of an encoding configuration of when carrying out encoding of three stages;

FIG. 9 is a view illustrating an example of an encoding configuration of when an exor method is used for the encoding of the second stage and a combining method is used for the encoding of the third stage; and

FIG. 10 is a view illustrating an example of an encoding configuration of when the combining method is used for the encoding of the second stage and the exor method is used for the encoding of the third stage.

### DETAILED DESCRIPTION

In general, according to one embodiment, a memory controller includes a first encoder configured to encode first data to generate a first codeword and to encode second data to generate a second codeword; an operation unit configured to perform exor operation with at least the first codeword and the second codeword as inputs to generate a first exor-codeword; a second encoder configured to encode the first exor-codeword to generate a second-stage parity; and a write control unit configured to write the first codeword, the second codeword, and the second-stage parity in a nonvolatile memory.

Exemplary embodiments of a memory controller, a storage device, and a memory control method will be explained below in detail with reference to the accompanying drawings. The present invention is not limited to the following embodiments.

### First Embodiment

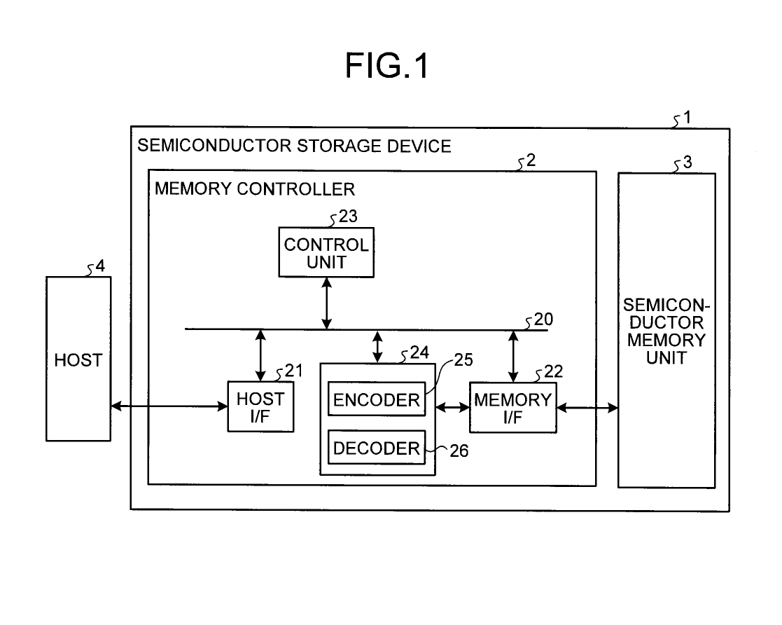

FIG. 1 is a block diagram illustrating a configuration example of a storage device (semiconductor storage device) according to a first embodiment. A semiconductor storage device 1 of the present embodiment includes a memory controller 2 and a nonvolatile memory (semiconductor memory unit) 3. The semiconductor storage device 1 is connectable with a host 4, where a state of being connected to the host 4 is illustrated in FIG. 1. The host 4 is an electronic device such as a personal computer, a portable terminal, and the like, for example.

The nonvolatile memory 3 is a nonvolatile memory that stores data in a nonvolatile manner, and is, for example, a NAND memory. An example of using the NAND memory for the nonvolatile memory 3 will be described herein, but a memory other than the NAND memory may be adopted. In the NAND memory, write and readout of the data are carried out for every write unit data generally called a page.

The memory controller 2 controls the write to the nonvolatile memory 3 in accordance with a write command from the host 4. The memory controller 2 controls the readout from the nonvolatile memory 3 in accordance with a readout command from the host 4. The memory controller 2 includes a Host I/F 21, a memory I/F 22 (write control unit), a control unit 23, and an encoder/decoder 24, which are connected to each other with an internal bus 20.

The Host I/F 21 outputs the command received from the host 4, the user data (write data), and the like to the internal bus 20. The Host I/F 21 transmits the user data read out from the nonvolatile memory 3, the response from the control unit 23, and the like to the host 4.

The memory I/F 22 controls the write process of the user data, and the like to the nonvolatile memory 3 and the readout process of the same from the nonvolatile memory 3 based on an instruction of the control unit 23.

The control unit 23 comprehensively controls the semiconductor storage device 1. The control unit 23 is, for example, a CPU (Central Processing Unit), an MPU (Micro Processing Unit), and the like. When receiving a command from the host 4 via the Host I/F 21, the control unit 23 performs the control corresponding to such command. For example, the control unit 23 instructs the memory I/F 22 on the write of the user data and the parity to the nonvolatile memory 3 according to the command from the host 4. Furthermore, the control unit 23 instructs the memory I/F 22 on the readout of the user data and the parity from the nonvolatile memory 3 according to the command from the host 4.

The control unit 23 determines a storage region (memory region) on the nonvolatile memory 3 with respect to the user data. The control unit 23 determines the memory region with respect to the data (page data) in units of pages, which is the write unit. In the present specification, the user data stored in one page of the nonvolatile memory 3 is defined as the unit data. The details on the unit data and the parity will be described later. In the present specification, the memory cell commonly connected to one word line is defined as a memory cell group. If the memory cell is a multi-level cell, the memory cell group corresponds to a plurality of pages. For example, if a multi-level cell in which two bits can be stored is used, the memory cell group corresponds to two pages. The control unit 23 determines the memory region of the nonvolatile memory 3 of the write destination for every unit data. A physical address is assigned to the memory region of the nonvolatile memory 3. The control unit 23 manages the memory region of the write destination of the unit data using the physical address. The control unit 23 instructs the memory I/F 22 to identify the determined memory region (physical address) and write the user data to the nonvolatile memory 3. The control unit 23 manages the correspondence of a logical address (logical address managed by the host 4) and the physical address of the user data. When a readout command including the logical address from the host 4 is received, the physical address corresponding to the logical address is specified, and identification of the physical address and the readout of the user data are instructed to the memory I/F 22.

The encoder/decoder 24 encodes the user data to generate parity. The encoder/decoder 24 includes an encoder 25 and a decoder 26. The encoder 25 encodes the user data to generate the parity. The decoder 26 performs decoding using the parity. The details of encoding and decoding of the present embodiment will be described later. Any code may be used for the error correction code, and for example, BCH code, RS (Reed-Solomon) code, and the like can be used. In the following description, an example of using the BCH code will be described. The encoding performed by the encoder 25 is not limited thereto, and merely needs to be a linear encoding.

In FIG. 1, a configuration example in which the memory controller 2 includes the encoder/decoder 24 and the memory I/F 22 is illustrated. However, the encoder/decoder 24 may be incorporated in the memory I/F 22.

The error correction encoding and decoding of the present embodiment will now be described. In the present embodiment, a parity of multi-stages is generated using a generating polynomial in an encoding (hereinafter referred to as incremental parity error correction encoding) based on the incremental parity error correcting method. The incremental parity error correcting method in the present embodiment refers to the encoding method that adopts a selecting method of the generating polynomial described in U.S. application Ser. No. 13/841,923. In this method, the generating polynomial used to generate the parity of i^{th} stage (i is an integer greater than or equal to one and smaller than or equal to n) is selected such that the root of the relevant generating polynomial continues to the root of the generating polynomial used to generate the parity of up to the (i-1)^{th} stage.

When encoding based on the multi-grain incremental parity error correcting method is carried out, the number (size) of the data that becomes the basis of generation of the parity can be changed for every stage using the incremental parity error correction encoding. The encoding based on the multi-grain incremental parity error correcting method in the present embodiment is the method of encoding described in U.S. application Ser. No. 13/724,337. Specifically, it is a method in which the selecting method of the generating polynomial described in U.S. application Ser. No. 13/841,923 is adopted, and the number (size) of the data that becomes the basis of generation of the parity is differed for every stage. The disclosures of U.S. application Ser. No. 13/724,337 and Ser. No. 13/841,923, are hereby incorporated by reference.

In the multi-grain incremental parity error correcting method described in U.S. application Ser. No. 13/724,337, the encoding is performed through the following procedure when generating the parity in two stages, for example. The data size of user data #1 and the data size of user data #2 are the same. The user data #1 and the user data #2 may be data stored on the same page of the nonvolatile memory 3, or may be data stored on different pages of the nonvolatile memory 3.

(1) A first-stage parity #1, which is the parity of the first stage, is calculated by G₁(x) using the user data #1, and a first-stage parity #2, which is the parity of the first stage, is calculated by G₁(x) using the user data #2.
(2) A second-stage parity, which is the parity of the second stage, is calculated by a generating polynomial G₂(x) using user data #1+first-stage parity #1+user data #2+first-stage parity #2.
(3) The parity is calculated by Gₚ(x) using the second-stage parity.

Here, Gᵢ(x) (i=0, 1, 2) is the generating polynomial, and the root of Gᵢ(x) continues to the root of Gᵢ₋₁(x) as described in U.S. application Ser. No. 13/724,337. Gₚ(x) is the generating polynomial selected irrespective of G₁(x), G₂(x), . . . , and may be any generating polynomial. The parity generated by Gₚ(x) is hereinafter referred to as an external parity.

If encoding is carried out through the above procedure, for example, the decoding of the user data #1 is performed through the following procedure.
(1) The error correction of the user data #1 (error correction of first stage) is performed using the first-stage parity #1.
   (2) If the error correction of (1) fails, the error correction of the second-stage parity is carried out using the external parity of the second-stage parity. The error correction (error correction of second stage) is performed using the first-stage parity #1, the first-stage parity #2, and the second-stage parity.

In the multi-grain incremental parity error correcting method described in U.S. application Ser. No. 13/724,337, the high-speed high error correcting capability is realized according to the above procedure. In a method (hereinafter referred to as method A) of simply carrying out the encoding in one stage rather than in the multi-grain incremental parity error correcting method, the parity is given to each individual user data of a small size such as the user data #1, the user data #2, and the like. Compared to the method A, in the multi-grain incremental parity error correcting method (hereinafter referred to as method B) described in U.S. application Ser. No. 13/724,337, the Galois field becomes larger than in the method A. Thus, for the data (user data #1, etc.) having a small size, the size of the parity necessary for correcting one bit (hereinafter referred to as the parity size per one bit correction) becomes larger in the method B than in the method A.

Similarly to the method B, the encoding of the first stage is performed, and thereafter, exor (exclusive or) of the user data+first-stage parity is calculated and the encoding of the second stage is carried out using the calculation result in the present embodiment. Thus, the parity size per one bit correction can be made smaller than in the method B while achieving the advantages of the multi-grain incremental parity error correcting method.

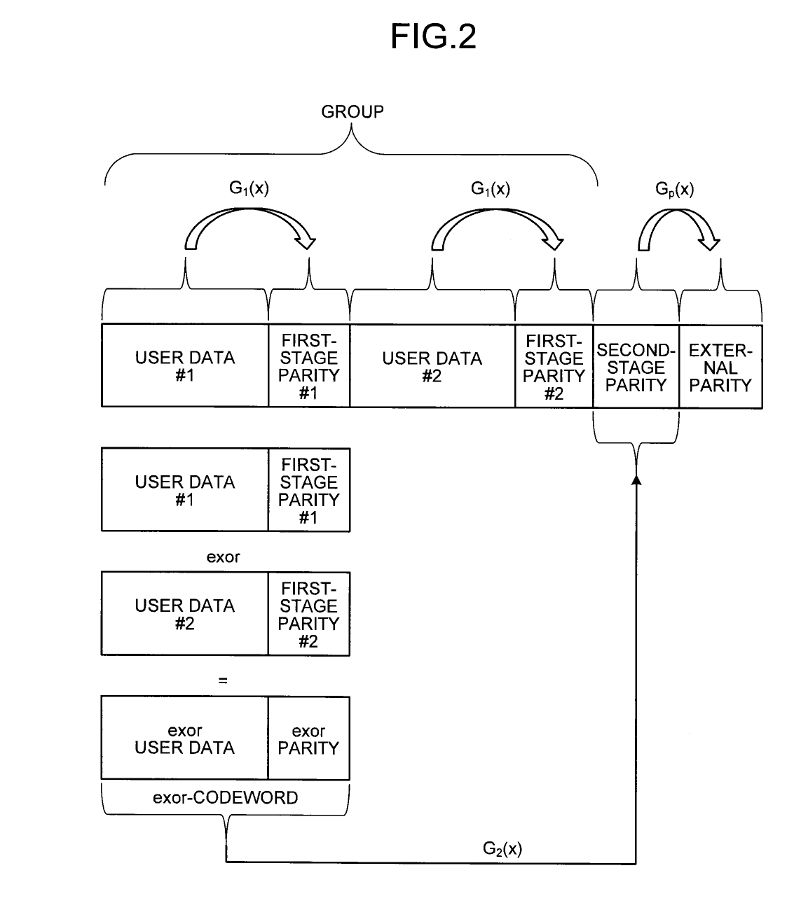

FIG. 2 is a view illustrating one example of an encoding configuration of the present embodiment. FIG. 2 illustrates an example of generating the parity of second stage using the two pieces of user data and the respective first-stage parity. The generating polynomials G₁(x), G₂(x), Gₚ(x) are generating polynomials used in the incremental parity error correcting method, similarly to method B.

In the example of FIG. 2, in the encoding of the first stage, the first-stage parity #1 is generated by G₁(x) using the user data #1, and the first-stage parity #2 is generated by G₁(x) using the user data #2. In the encoding of the second stage, exor of the user data #1+first-stage parity #1 and the user data #2+first-stage parity #2 is calculated, and the second-stage parity is generated by G₂(x) using the calculation result (exor-codeword). The external parity is generated by Gₚ(x) using the second-stage parity. An example of generating the external parity is described herein, but the external parity may not be generated.

Thus, in the present embodiment, the Galois field becomes small compared to method B since the parity of the second stage is generated using the exor calculation result. Therefore, the parity size per one bit correction is smaller than method B in the present embodiment.

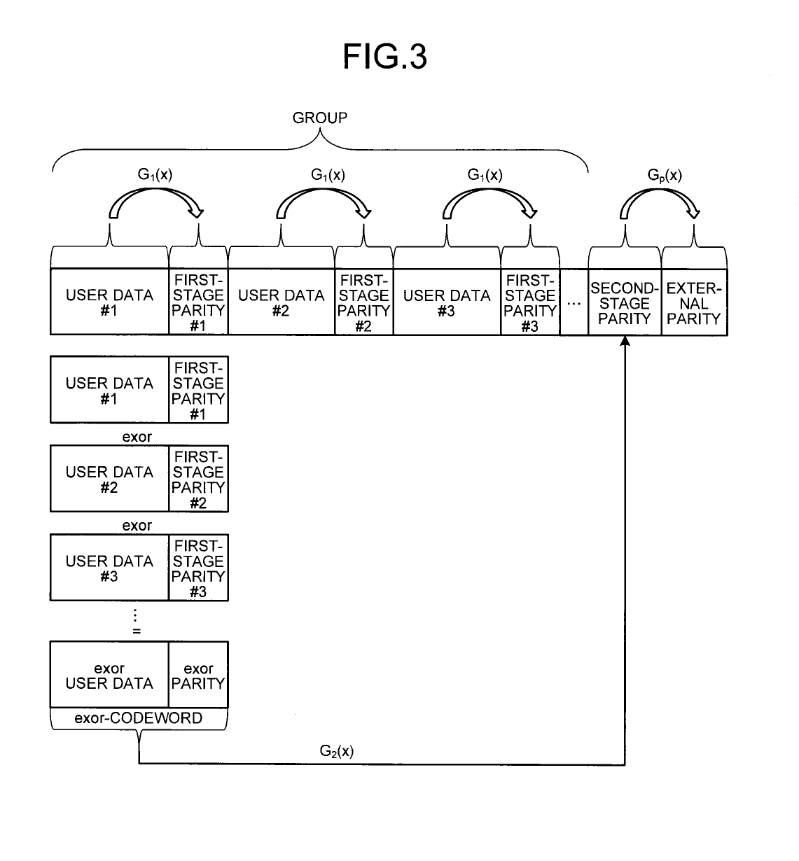

In FIG. 2, the exor of the two pieces of user data and the first-stage parity is calculated, and the second-stage parity is generated using the calculation result. As illustrated in FIG. 2, the user data and the first-stage parity, which become the basis of generation of the second-stage parity, are assumed as a group. The number of user data (=number of first-stage parities) contained in the group is not limited to the example of FIG. 2. FIG. 3 is a view illustrating one example of an encoding configuration of when three or more pieces of user data are contained in the group. Assuming the number of user data contained in the group is n, the corresponding first-stage parity is generated using each user data in the encoding of the first stage. In the encoding of the second stage, exor of the user data #1+first-stage parity #1, the user data #2+first-stage parity #2, user data #3+first-stage parity #3, . . . , user data #n+first-stage parity #n is calculated. Thereafter, the second-stage parity is generated by G₂(x) using the calculation result.

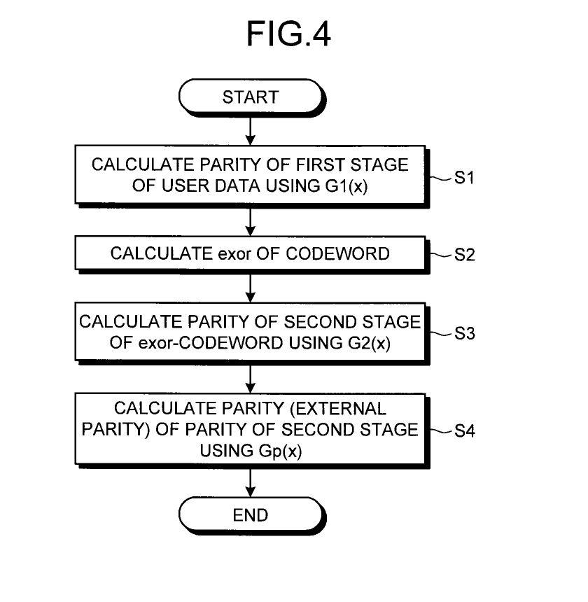

FIG. 4 is a view illustrating one example of an encoding procedure of the present embodiment. As illustrated in FIG. 4, the encoder 25 first calculates the parity of the first stage (first-stage parity) for every user data using the generating polynomial G₁(x) for all the user data in the group (step S1). The encoder 25 then calculates exor of the user data #1+first-stage parity #1, the user data #2+first-stage parity #2, the user data #3+first-stage parity #3, . . . , the user data #n+first-stage parity #n. In other words, the encoder 25 calculates the exor of the codeword (one user data and corresponding first-stage parity) (step S2). The calculation result (exor-codeword) is configured by the exor user data corresponding to the exor of the user data and the exor parity corresponding to the exor of the first-stage parity, as illustrated in FIGS. 2 and 3.

Specifically, the exor-codeword is calculated in the following manner. The codeword configured by the user data #1 and the first-stage parity #1 is assumed as codeword #1, and the bit value of the j^{th} bit of the codeword #1 is assumed as b₁(j). The codeword configured by the user data #2 and the first-stage parity #2 is assumed as codeword #2, and the bit value of the j^{th} bit of the codeword #2 is assumed as b₂(j). The number of bits of each codeword is assumed as na, and the bit from 0^{th} to nd^{th} is assumed as the user data portion. The encoder 25 obtains the j^{th} bit value ex(j) of the exor-codeword according to the following equation (1).

ex(j)=b₁(j) exor b₂(j) (1)

The encoder 25 calculates the exor-codeword by obtaining ex(j) from j=0 to j=na. Here, ex(0), ex(1), . . . , ex(nd) are the exor user data, and ex(nd+1), ex(nd+2), . . . , ex(na) are the exor parities.

The encoder 25 then calculates the parity of the second stage (second-stage parity) of the exor-codeword calculated in step S2 using the generating polynomial G₂(x) (step S3). The encoder 25 calculates the parity (external parity) of the second-stage parity using the generating polynomial Gₚ(x) (step S4). Step S4 is not performed if the external parity is not used.

After the encoding is carried out through the above procedure, each piece of user data is stored in the nonvolatile memory 3. As described above, the user data in the group may all be stored on the same page, or the user data in the group may be stored in a plurality of pages. The storing location of the first-stage parity, the second-stage parity, and the external parity is not restricted, and may be the nonvolatile memory 3 or other media. If the first-stage parity is stored on the same page as the corresponding user data, the first-stage parity is simultaneously read out when reading out the user data, and thus the readout can be efficiently carried out.

A set of data and parity (all user data and first-stage parity configuring one group, second-stage parity, external parity) illustrated in FIG. 2 and FIG. 3 may be stored on the same page of the nonvolatile memory 3.

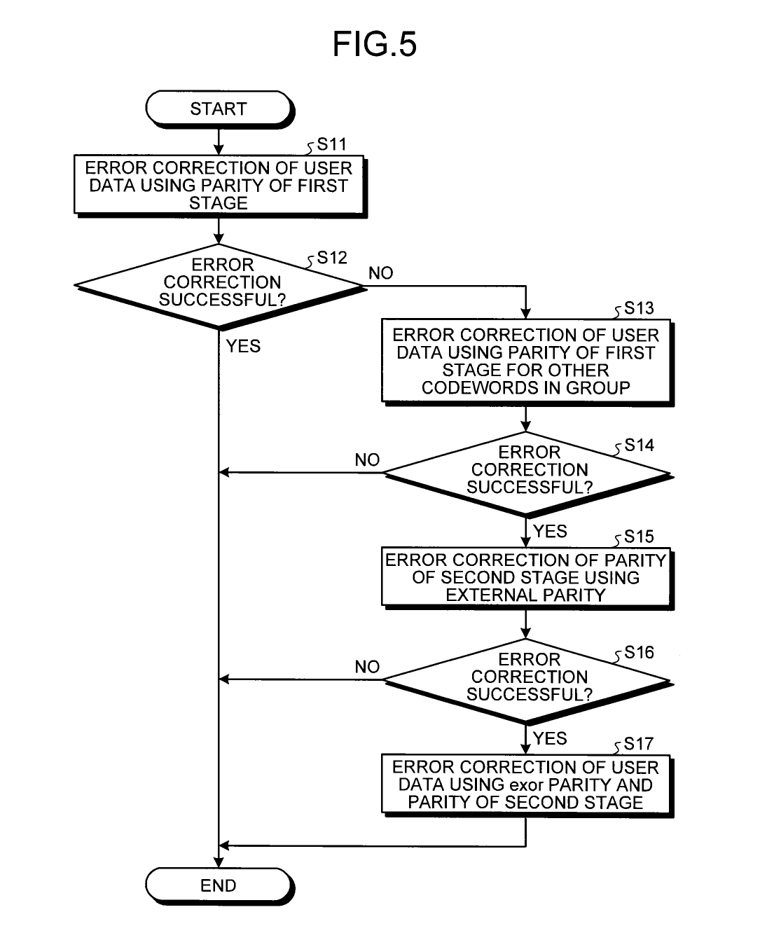

Next, the decoding process of the present embodiment will be described. When reading out the user data stored in the nonvolatile memory 3, the memory controller 2 performs the decoding process (error correction) using the parity on the readout user data. FIG. 5 is a view illustrating one example of the decoding procedure of the present embodiment. The decoder 26 performs the error correction using the parity of the first stage (first-stage parity) on the user data to be corrected (step S11). The decoder 26 determines whether or not the error correction of the user data to be corrected is successful (step S12), and terminates the process if successful (step S12 Yes).

The following two cases may be combined, and simply phrased as being successful in error correction.
When error does not exist without even carrying out error correction
When error exists, and error is corrected by carrying out error correction

If the error correction of the user data to be corrected is not successful (step S12 No), the error correction is carried out using the parity of the first stage on the other codewords (user data+first-stage parity) in the group to which the user data to be corrected belongs (step S13). The decoder 26 then determines whether or not the error correction of all other codewords in the group, to which the user data to be corrected belongs, is successful (step S14).

If the error correction of all other codewords in the group is successful (step S14 Yes), the error correction of the parity of the second stage is carried out using the external parity (step S15). Whether or not the error correction of the parity of the second stage using the external parity is successful is then determined (step S16). If successful (step S16 Yes), the error correction of the user data to be corrected is carried out using the exor parity and the parity of the second stage of after the error correction (step S17).

Specifically, for example, the following process is performed in step S17. First, the decoder 26 calculates the exor of all other codewords in the group of after the error correction and the codeword including the user data to be corrected. For example, assume the group contains two pieces of user data as in the example of FIG. 2, where the user data #1 is the correcting target and the error correction by the first-stage parity #1 failed, and the error correction by the first-stage parity #2 is successful in the user data #2. Furthermore, also assume that the error correction of the second-stage parity using the external parity is successful.

In this case, the user data #2 and the first-stage parity #2 do not have an error, and thus each bit of the codeword #2 is exactly the same as b₂(j) illustrated in equation (1) described above. The user data #1 and the first-stage parity #1 (codeword #1) include an error. Assume each bit value of the codeword #1 including the error is b₁′(j). The decoder 26 calculates the exor of the codeword #2 of after the error correction and the codeword #1 including the error. Specifically, the calculation of the following equation (2) is performed from j=0 to j=na.

ex′(j)=b₁′(j) exor b₂(j) (2)

Here, ex′(0), ex′(1), . . . , ex′(nd) are the exor user data in the decoding process, and ex′(nd+1), ex′(nd+2), . . . , ex′(na) are the exor parities in the decoding process.

The error correction of the exor user data is carried out using the exor parity and the parity of the second stage of after the error correction. This error correction is a process similar to the error correction of the second stage in the incremental parity error correcting method (non-multigrain incremental parity error correcting method) described in U.S. application Ser. No. 13/841,923. In step S16, the error correction of all other codewords in the group is successful, and hence the error in the exor-codeword originates from the error of the codeword corresponding to the user data to be corrected. Assuming the bit positions where the error occurred in the codeword #1 are je₁, je₂, . . . , jeₙₑ, b₁′(j)≠b₁(j) is obtained at the bit values where j=je₁, je₂, . . . , jeₙₑ, and thus ex′(j)≠ex(j). Furthermore, b₁′(j)=b₁(j) is obtained at the bit values where j≠je₁, je₂, . . . , jeₙₑ, and thus ex′(j)=ex(j).

In other words, the error position detected in the error correction of the exor user data corresponds to the error position of the user data to be corrected. Thus, the user data to be corrected can be corrected by correcting the error position detected in the error correction of the exor user data with respect to the user data to be corrected. This is similar in a case where three or more pieces of user data configure the group. For example, if four pieces of user data configure the group, when the error of the user data cannot be corrected using the first-stage parity, the error of all the user data in the group can be corrected if the error correction using the first-stage parity of the three other pieces of user data in the group is successful.

If at least one of the other codewords in the group failed in the error correction in step S14 (step S14 No), the process is terminated. In this case, the decoder 26 notifies the control unit 23 that the error correction failed. If determined that the error correction failed in step S16 (step S16 No), the process is terminated, and the decoder 26 notifies the control unit 23 that the error correction failed. Similarly, if the error correction failed in step S17, notification is similarly made to the control unit 23 that the error correction failed. The control unit 23 performs a predetermined procedure (e.g., notify that the readout user data contains error to the host 4, etc.) of when the error correction failed. There is no restriction on the operation after the error correction failed.

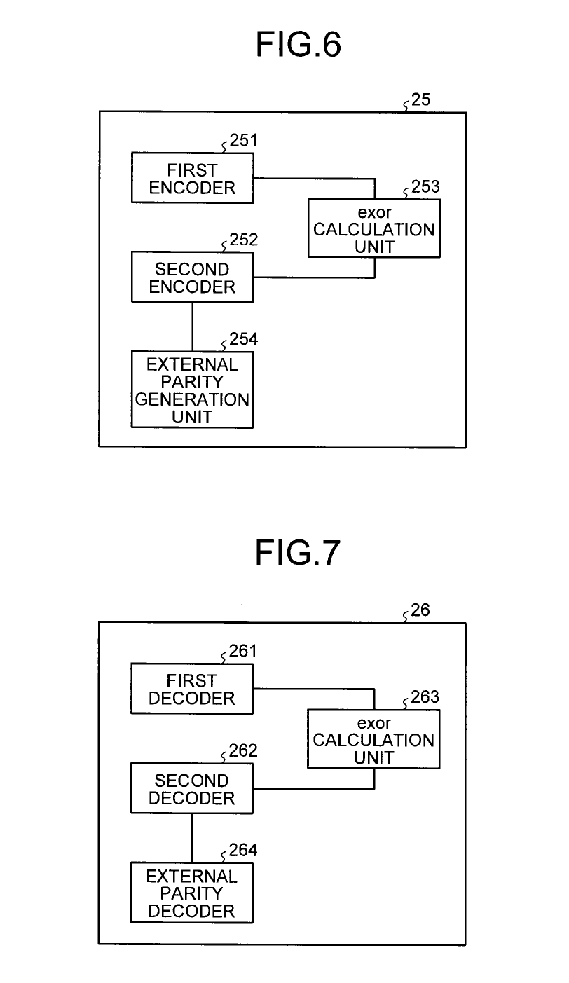

FIG. 6 is a view illustrating a configuration example of the encoder 25. The encoder 25 includes a first encoder 251, a second encoder 252, an exor calculation unit 253 and an external parity generation unit (parity generation unit) 254.

FIG. 7 is a view illustrating a configuration example of the decoder 26. The decoder 26 includes a first decoder 261, a second decoder 262, an exor calculation unit 263, and an external parity decoder 264.

FIG. 6 is one example, and the configuration of the encoder 25 is not limited to such configuration. For example, two or more of the first encoder 251, the second encoder 252, and the external parity generation unit 254 may be realized with one encoding unit. This is similar for the decoder 26, and two or more of the first decoder 261, the second decoder 262, and the external parity decoder 264 may be realized with one decoding unit. One or more configuring elements may be shared by the encoder 25 and the decoder 26.

As described above, in the present embodiment, the encoding of the first stage is performed, and thereafter, exor of the user data+first-stage parity is calculated, and the encoding of the second stage is carried out using the calculation result. Thus, the parity size per one bit correction can be reduced compared to the multi-grain incremental parity error correcting method in which the calculation of exor is not used. Furthermore, the parity size per one bit correction can be reduced even compared to the incremental parity error correcting method (non-multigrain incremental parity error correcting method) described in Ser. No. 13/841,923.

### Second Embodiment

In the first embodiment, an example of performing the two-stage encoding has been described. Similarly to the (non-multigrain) incremental parity error correcting method and the multi-grain incremental parity error correcting method, the encoding using exor of the first embodiment can also be applied to the encoding of three or more stages. The configuration of the storage device 1 of the present embodiment is similar to the first embodiment.

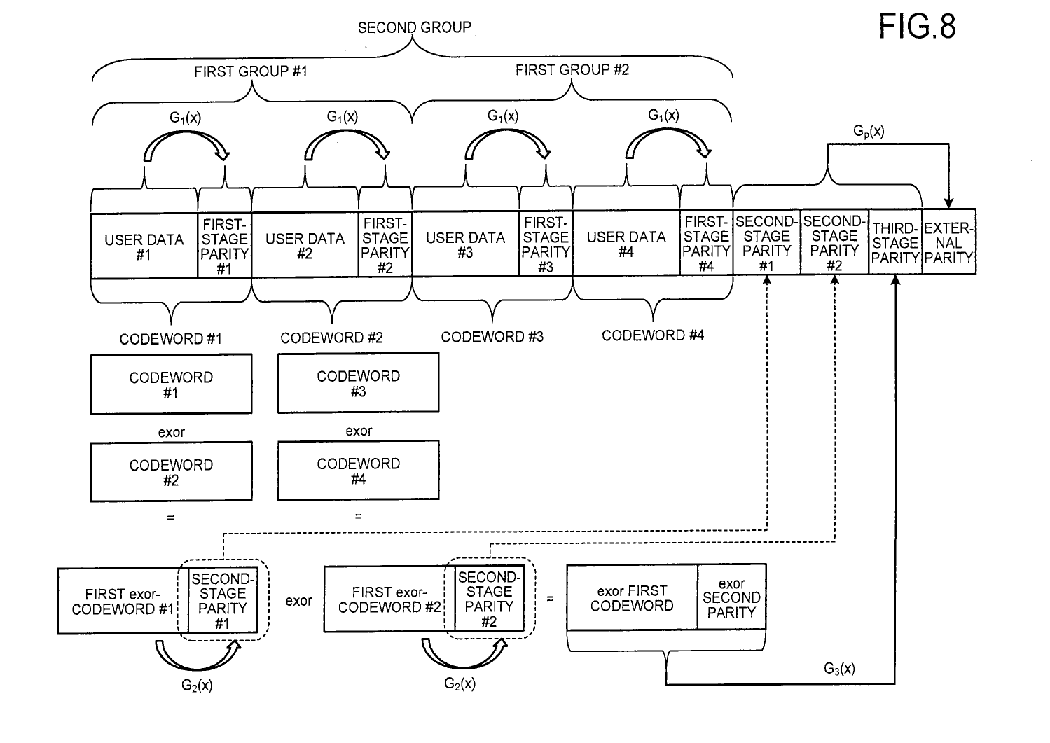

FIG. 8 is a view illustrating one example of the encoding configuration of when carrying out encoding of three stages. In the present embodiment, the user data and the first-stage parity, which become the basis of generation of the parity of the second stage, are assumed as a first group; and the user data and first-stage parity, which become the basis of generation of the parity of the third stage, are assumed as a second group. In the example of FIG. 8, the first group contains two user data, and the second group contains four user data. The number of user data configuring the first group and the number of user data configuring the second group are not limited to the example of FIG. 8.

As the encoding of the first stage, the encoder 25 calculates the first-stage parity #1, the first-stage parity #2, the first-stage parity #3, and the first-stage parity #4 by the generating polynomial G₁(x) using the user data #1, the user data #2, the user data #3, and the user data #4. The first group #1 is configured by the user data #1+first-stage parity #1 (codeword #1) and the user data #2+first-stage parity #2 (codeword #2). The first group #2 is configured by the user data #3+first-stage parity #3 (codeword #3) and the user data #4+first-stage parity #4 (codeword #4). The second group is configured by the first group #1 and the first group #2.

The generating polynomials G₁(x), G₂(x), G₃(x) are the generating polynomials of the first stage, the second stage, and the third stage in the incremental parity error correcting method described in U.S. application Ser. No. 13/841,923. The generating polynomial Gₚ(x) is an arbitrary generating polynomial, similarly to the first embodiment.

As the encoding of the second stage, the encoder 25 first calculates the exor of the codeword #1 and the codeword #2, similarly to the first embodiment. As illustrated in FIG. 8, the calculation result is assumed as the first exor-codeword #1. The encoder 25 calculates the second-stage parity #1 by the generating polynomial G₂(x) using the first exor-codeword #1. Similarly, the encoder 25 calculates the exor of the codeword #3 and the codeword #4. This calculation result is assumed as the first exor-codeword #2. The encoder 25 calculates the second-stage parity #2 by the generating polynomial G₂(x) using the first exor-codeword #2.

Furthermore, the encoder 25 first calculates exor of the first exor-codeword #1 and the first exor-codeword #2 as the encoding of the third-stage. This calculation result is assumed as the exor first codeword (second-stage exor-codeword). The encoder 25 then calculates the third-stage parity by the generating polynomial G₃(x) using the exor first codeword.

The encoder 25 calculates the external parity by Gₚ(x) using the second-stage parity #1, the second-stage parity #2, and the third-stage parity. The external parity is calculated with respect to the second-stage parity #1, the second-stage parity #2, and the third-stage parity, but the external parity may be individually calculated for the first-stage parity #1, the second-stage parity #2, and the third-stage parity.

The user data #1 to the user data #4 are stored in the nonvolatile memory 3. The storage area of the first-stage parity #1, the second-stage parity #2, the third-stage parity, and the external parity may be the nonvolatile memory 3, or may be other media, similarly to the first embodiment.

The decoding process is carried out at the time of readout from the nonvolatile memory 3. First, the following process A is performed.

### (Process (A))

The process up to the error correction of the second stage related to the user data to be corrected is similar to the first embodiment. For example, when decoding the user data #1, the error correction is first performed using the first-stage parity #1, and if the error correction fails, the error correction of other codewords of the first group #1 is performed. If the error correction of all other codewords of the first group #1 is successful, the error correction of the second stage is performed using the second-stage parity #1. The process up to here is referred to as process (A). The first exor-codeword is calculated in the course of the error correction, and such first exor-codeword is held.

If the error correction of the second stage fails in the process (A), the decoder 26 performs the process (B) illustrated below.

### (Process (B))

The error correction of the first stage is performed based on the user data and the first-stage parity of the other first group in the second group to which the user data to be corrected belongs.

If the error correction of all the codewords in the first group (other first group in the second group to which the user data to be corrected belongs) is successful in process (B), the process (C) illustrated below is performed.

### (Process (C))

The error correction is first carried out using the external parity for the second-stage parity corresponding to the user data in the other first group in the second group. When the error correction using the external parity is carried for the second-stage parity corresponding to the user data to be corrected, the result of carrying out the error correction is also held for the other second-stage parities and the third-stage parity, and the held second-stage parity of after the error correction may be used. The decoder 26 calculates the exor of the codeword in the first group (other first group in the second group to which the user data to be corrected belongs) to obtain the first exor-codeword. The exor of the first exor-codeword+corresponding second-stage parity of after the error correction, and the first exor-codeword (first exor-codeword in which the error is not corrected with the error correction of the second stage) held in the process (A)+corresponding second-stage parity of after the error correction. The decoder 26 performs the error correction using the calculation result and the third-stage parity of after the error correction. If the error correction is successful, the error correction of the first exor-codeword in which the error is not corrected with the error correction of the second stage becomes successful, and furthermore, the correction of the original user data to be corrected becomes successful.

The decoder 26 performs the following process (D) if one of the codewords of the first group (other first groups in the second group to which the user data to be corrected belongs) is not error corrected as a result of the process (B).

### (Process (D))

The decoder 26 first performs the error correction of the second stage of the first embodiment with the codeword in which the error correction is not carried out as the correcting target. If the error correction is successful, the exor of the first exor-codeword calculated in the course of the process (D)+corresponding second-stage parity (second-stage parity of after the error correction by the external parity) and the first exor-codeword (first exor-codeword in which the error is not corrected with the error correction of the second stage)+the corresponding second-stage parity of after the error correction held in the process (A) is calculated. The decoder 26 then performs the error correction using the calculation result and the third-stage parity of after the error correction.

For example, in the example of FIG. 8, the process (A) is carried out with the user data #1 as the correcting target. Assume that the error correction failed in the error correction of the second stage. In this case, the error correction of the codeword #3 and the codeword #4 belonging to the first group #2 is performed in the process (B). If the error correction of both the codeword #3 and the codeword #4 is successful, the exor of the codeword #3 of after the error correction and the codeword #4 of after the error correction is calculated for the process (C). The calculation result corresponds to the first exor-codeword #2 of FIG. 8. The first exor-codeword #1 including error is calculated in the course of the process (A). The decoder 26 calculates the exor of the first exor-codeword #1 including error+the second-stage parity #1 of after the error correction and the first exor-codeword #2 (not including error)+the second-stage parity #1 of after the error correction, and performs the error correction using the calculation result and the third-stage parity of after the error correction. The error of the user data #1 is thereby corrected.

In the example of FIG. 8, the process (A) is carried out with the user data #1 as the correcting target, where the error correction failed in the error correction of the second stage, the codeword #3 succeeded in the error correction in the process (B), and the codeword #4 failed in the error correction. In this case, the process proceeds to the process (D), and the error correction of the second stage of the first embodiment is performed with the codeword #4 as the correcting target. If such error correction is successful, the exor of the first exor-codeword calculated in the course of the process (D)+corresponding second-stage parity (second-stage parity of after the error correction by the external parity) and the first exor-codeword held in the process (A) (first exor-codeword in which the error is not corrected with the error correction of the second stage)+corresponding second-stage parity of after the error correction. The error of the user data #1 is thereby corrected.

In the example of FIG. 8, an example of performing encoding (referred to as exor method) using the exor operation in the encoding of the second stage and the third stage has been described, but the encoding (referred to as combining method) of the multi-grain incremental parity error correcting method, in which the exor operation is not used, and the exor method may coexist.

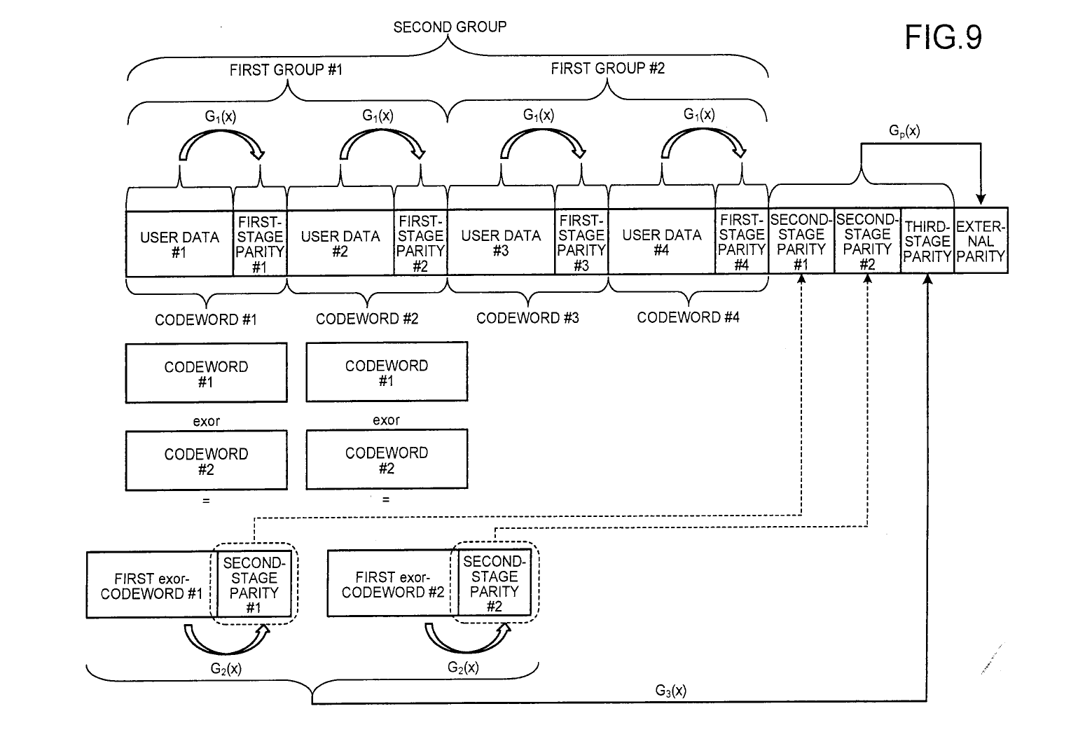

FIG. 9 is a view illustrating one example of an encoding configuration of when the exor method is used for the encoding of the second stage and the combining method is used for the encoding of the third stage. The method of generating the first exor-codeword #1, the first exor-codeword #2, the second-stage parity #1, and the second-stage parity #2 is similar to the example of FIG. 8. In the example of FIG. 9, the encoder 25 performs the encoding of the combining method for the encoding of the third stage. In other words, the third-stage parity is calculated by G₃(x) using the first exor-codeword #1 and the first exor-codeword #2 of the second group.

The process at the time of decoding is similar to the example of FIG. 8 for the processes (A) and (B). If the error correction of all the codewords in the first group (other first group in the second group to which the user data to be corrected belongs) is successful in the process (B), the process (C′) illustrated below is performed.

### (Process (C′))

Similarly to the process (C) described above, the decoder 26 calculates the exor of the codewords in the first group (other first group in the second group to which the user data to be corrected belongs) to obtain the first exor-codeword. The error correction is then carried out using the first exor-codeword+corresponding second-stage parity of after the error correction, the first exor-codeword held in the process (A) (first exor-codeword in which the error is not corrected with the error correction of the second stage)+corresponding second-stage parity of after the error correction, and the third-stage parity of after the error correction.

If one of the codewords of the first group (other first group in the second group to which the user data to be corrected belongs) is not error corrected as a result of the process (B), the following process (D′) is performed.

### (Process (D′))

Similarly to the process (D), the error correction of the second stage of the first embodiment is first performed with the codeword, in which error correction is not carried out, as the correcting target. If such error correction is successful, the error correction is carried out using the first exor-codeword calculated in the course of the process (D)+corresponding second-stage parity (second-stage parity of after the error correction by the external parity), and the first exor-codeword held in the process (A) (first exor-codeword in which the error is not corrected with the error correction of the second stage)+corresponding second-stage parity of after the error correction, and the third-stage parity of after the error correction.

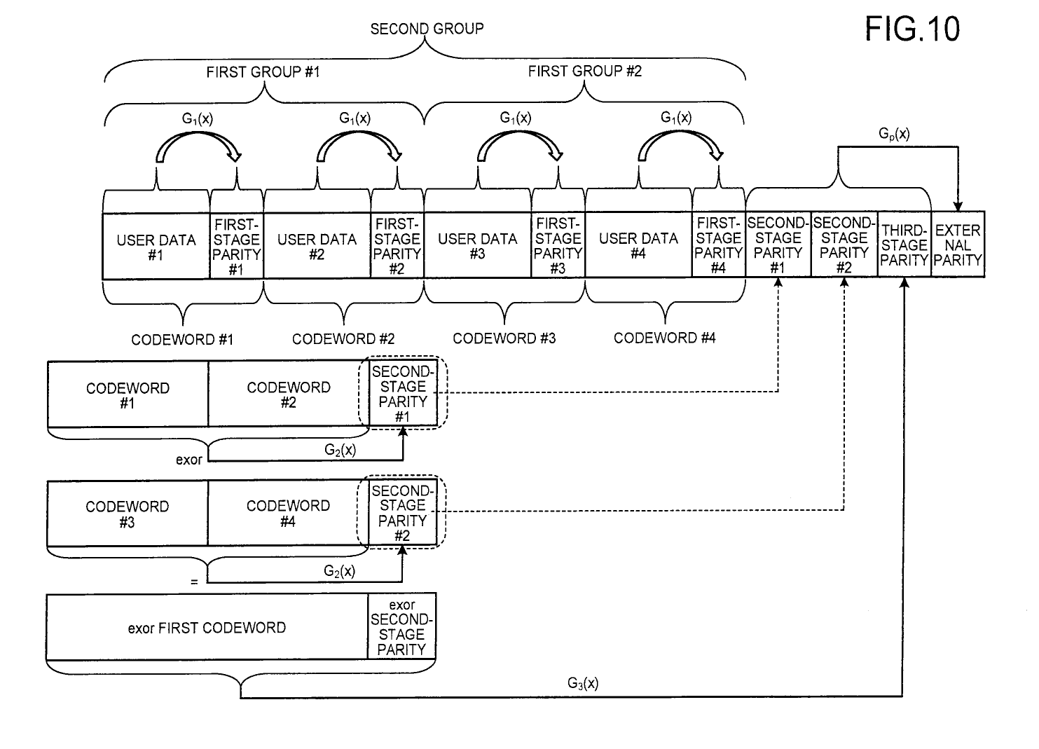

FIG. 10 is a view illustrating one example of the encoding configuration of when the combining method is used for the encoding of the second stage and the exor method is used for the encoding of the third stage. The method for generating the first-stage parity is similar to the examples of FIGS. 8 and 9. After the generation of the first-stage parity, the second-stage parity is generated by G₂(x) based on the codewords in the first group for every first group configuring the second group. The exor of the codewords in the first group in the second group+second-stage parity is calculated. The third-stage parity is generated by G₃(x) using the exor calculation result.

The process at the time of decoding is similar to the error correction of the first stage and the second stage in the incremental parity error correcting method described in U.S. application Ser. No. 13/841,923 up to the error correction of the second stage using the first-stage parity. If the error correction of the second stage fails, the decoder 26 calculates the exor of the codewords in the first group including the codeword to be corrected+second-stage parity. The error correction process is carried out using the calculation result, and the third-stage parity of after the correction by the external parity.

For example, assume that the error cannot be corrected with the error correction up to the second stage when the user data #1 is the correcting target in the example of FIG. 10. In this case, the exor of the codeword #1+codeword #2 of after the correction+the second-stage parity of after the correction, and the codeword #3 of after the correction+the codeword #4 of after the correction+the second-stage parity of after the correction is calculated. The error correction process is carried out using the calculation result and the third-stage parity of after the correction by the external parity.

As described above, an example of performing encoding of three stages by the multigrain incremental parity error correcting method using the calculation of exor has been described in the present embodiment. In the present embodiment, the parity size per one bit correction can be reduced compared to the three-stage encoding method of the multi-grain incremental parity error correcting method that does not use the calculation of exor. The parity size per one bit correction can be reduced even compared with the incremental parity error correcting method (non-multigrain incremental parity error correcting method) described in Ser. No. 13/841,923. In the present embodiment, the encoding of three stages has been described, but the encoding of four or more stages can be similarly performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller configured to control a nonvolatile memory, the memory controller comprising:
a first encoder configured to encode first data to generate a first codeword, and encode second data to generate a second codeword, the first codeword being configured by the first data and a first first-stage parity generated with respect to the first data, and the second codeword being configured by the second data and a second first-stage parity generated with respect to the second data;
an operation unit configured to perform an exor operation with at least the first codeword and the second codeword as inputs to generate a first exor-codeword;
a second encoder configured to encode the first exor-codeword to generate a first second-stage parity; and
a write control unit configured to write the first codeword, the second codeword, and the first second-stage parity to the nonvolatile memory.

2. The memory controller according to claim 1, wherein the encoding carried out by the first encoder and the second encoder is a linear encoding.

3. The memory controller according to claim 1, wherein a generating polynomial used in the generation of the first codeword, and a generating polynomial used in the generation of the second codeword are the same.

4. The memory controller according to claim 1, wherein a generating polynomial used in the encoding carried out by the first encoder is assumed as a first generating polynomial, and a generating polynomial used in the encoding carried out by the second encoder is assumed as a second generating polynomial, the second generating polynomial having a root continuing to a root of the first generating polynomial.

5. The memory controller according to claim 1, further comprising a parity generation unit configured to generate a parity by encoding the first second-stage parity.

6. The memory controller according to claim 1, wherein the write control unit writes the first codeword, the second codeword, and the first second-stage parity on the same page of the nonvolatile memory.

7. The memory controller according to claim 1, wherein the write control unit writes at least a part of the first codeword, the second codeword, and the first second-stage parity on a different page of the nonvolatile memory.

8. The memory controller according to claim 1, further comprising:
a first decoder configured to perform an error correction decoding process based on the first codeword, and to perform an error correction decoding process based on the second codeword; and
a second decoder configured to perform an error correction decoding process using the first codeword, the second codeword, and the first second-stage parity when the error correction decoding process by the first decoder fails.

9. The memory controller according to claim 1, wherein
the first encoder further performs encoding with respect to third to n^{th} data, n being an integer of greater than or equal to three, to generate third to n^{th} codewords;
the operation unit performs exor operation of the first codeword to the n^{th} codeword to generate the first exor-codeword; and
the write control unit writes the third to n^{th} codewords, and the first to n^{th} second-stage parities in the nonvolatile memory.

10. The memory controller according to claim 1, wherein the first encoder further performs encoding with respect to third data to generate a third codeword, and performs encoding with respect to fourth data to generate a fourth codeword;
the operation unit further performs exor operation with the third codeword and the fourth codeword as inputs to generate a second exor-codeword;
the second encoder further performs encoding with respect to the second exor-codeword to generate a second second-stage parity;
the memory controller further includes a third encoder configured to perform an exor operation of the first exor-codeword and the second exor-codeword to generate a second-stage exor-codeword, and encode with respect to the second-stage exor-codeword to generate a third-stage parity; and
the write control unit writes the third codeword, the fourth codeword, the second second-stage parity, and the third-stage parity in the nonvolatile memory.

11. The memory controller according to claim 10, further comprising a parity generation unit configured to generate a parity by encoding the first second-stage parity, the second second-stage parity, and the third-stage parity.

12. The memory controller according to claim 10, wherein the write control unit writes the first codeword, the second codeword, the third codeword, the fourth codeword, the first second-stage parity, the second second-stage parity, and the third-stage parity on the same page of the nonvolatile memory.

13. The memory controller according to claim 10, wherein the write control unit writes at least a part of the first codeword, the second codeword, the third codeword, the fourth codeword, the first second-stage parity, the second second-stage parity, and the third-stage parity on a different page of the nonvolatile memory.

14. The memory controller according to claim 10, further comprising:
a first decoder configured to perform an error correction decoding process based on the first codeword, and to perform an error correction decoding process based on the second codeword;
a second decoder configured to perform an error correction decoding process using the first codeword, the second codeword, and the first second-stage parity when the error correction decoding process by the first decoder fails; and
a third decoder configured to perform an error correction decoding process using the first codeword, the second codeword, the third codeword, the fourth codeword, the first second-stage parity, the second second-stage parity, and the third-stage parity when the error correction decoding process by the first decoder fails.

15. The memory controller according to claim 1, wherein
the first encoder further performs encoding with respect to third data to generate a third codeword, and performs encoding with respect to fourth data to generate a fourth codeword;
the operation unit further performs exor operation with the third codeword and the fourth codeword as inputs to generate a second exor-codeword;
the second encoder further performs encoding with respect to the second exor-codeword to generate a second second-stage parity; and
the memory controller further includes a third encoder configured to encode the first exor-codeword and the second exor-codeword to generate a third-stage parity; wherein
the write control unit further writes the third codeword, the fourth codeword, the second second-stage parity, and the third-stage parity in the nonvolatile memory.

16. A storage device comprising:
a nonvolatile memory;
a first encoder configured to encode first data to generate a first codeword, and to encode second data to generate a second codeword, the first codeword being configured by the first data and a first first-stage parity generated with respect to the first data, and the second codeword being configured by the second data and a second first-stage parity generated with respect to the second data;
an operation unit configured to perform an exor operation with at least the first codeword and the second codeword as inputs to generate a first exor-codeword;
a second encoder configured to encode the first exor-codeword to generate a first second-stage parity; and
a write control unit configured to write the first codeword, the second codeword, and the first second-stage parity in the nonvolatile memory.

17. A memory control method for controlling a nonvolatile memory, the memory control method comprising the steps of:
performing encoding with respect to first data to generate a first codeword, and performing encoding with respect to second data to generate a second codeword, the first codeword being configured by the first data and a first first-stage parity generated with respect to the first data, and the second codeword being configured by the second data and a second first-stage parity generated with respect to the second data;
performing an exor operation with at least the first codeword and the second codeword as inputs to generate a first exor-codeword;
performing encoding with respect to the first exor-codeword to generate a first second-stage parity; and
writing the first codeword, the second codeword, and the first second-stage parity in the nonvolatile memory.
